(19) United States
(12) Patent Application Publication
(10) Pub. No.: US 2013/0128678 A1
(43) Pub. Date: May 23, 2013

(54) POWER SAVING METHODS FOR USE IN A SYSTEM OF SERIALLY CONNECTED SEMICONDUCTOR DEVICES

(71) Applicant: Hong Beom PYEON, Kanata (CA)

(72) Inventor: Hong Beom PYEON, Kanata (CA)

(21) Appl. No.: 13/425,801

(22) Filed: Mar. 21, 2012

Related U.S. Application Data
(60) Provisional application No. 61/562,241, filed on Nov. 21, 2011.

(51) Int. Cl. G11C 7/00

(52) U.S. Cl. 365/194; 365/191

(57) ABSTRACT

A semiconductor device comprising (i) internal circuitry for outputting at least one internal clock signal and at least one internal data/control signal for transmission to a next device in a chain of semiconductor devices; (ii) data/control output circuitry for outputting at least one output data/control signal from the at least one internal data/control signal and for releasing the at least one output data/control signal towards the next device via at least one output data/control signal line, the at least one output data/control signal having a first dynamic range; and (iii) clock output circuitry for generating at least one output clock signal from the at least one internal clock signal and for releasing the at least one output clock signal towards the next device via at least one output clock signal line, the at least one output clock signal having a dynamic range different than the first dynamic range.

### CROSS-REFERENCE TO RELATED APPLICATION

The present application claims the benefit under 35 U.S.C. 119(e) of U.S. Provisional Application Ser. No. 61/562,241 to Pyeon, filed on Nov. 21, 2011 and hereby incorporated by reference herein.

### TECHNICAL FIELD

The present invention relates generally to techniques for reducing power consumption in a system having semiconductor devices.

### BACKGROUND

Systems including semiconductor devices, such as, for example, memory devices, require power in order to operate. In these and other systems, there is a need to reduce power consumption, particularly but not exclusively when this power comes from a battery. In the case of a serial connection configuration, which can support numerous serially interconnected memory devices, power consumption can rise dramatically as the number of devices increases. Therefore, advanced techniques are required which are applicable to such a configuration.

### SUMMARY

A first broad aspect of the invention seeks to provide a semiconductor device, which comprises (i) internal circuitry for outputting at least one internal clock signal and at least one internal data/control signal; (ii) data/control output circuitry for outputting at least one output data/control signal from the at least one internal data/control signal and for releasing the at least one output data/control signal towards a next device in a chain of semiconductor devices via at least one output data/control signal line, the at least one output data/control signal having a first dynamic range; and (iii) clock output circuitry for generating at least one output clock signal from the at least one internal clock signal and for releasing the at least one output clock signal towards the next device via at least one output clock signal line, the at least one output clock signal having a second dynamic range different than the first dynamic range.

A second broad aspect of the invention seeks to provide a semiconductor device, which comprises (i) clock output circuitry for outputting at least one output clock signal from at least one first internal clock signal, the clock output circuitry providing a first propagation delay therethrough; (ii) non-clock output circuitry for outputting at least one output non-clock signal from at least one internal non-clock signal, the non-clock output circuitry providing a second propagation delay therethrough; (iii) a clock producer for producing a second internal clock signal and a third internal clock signal, the clock producer comprising circuitry for synchronizing the first internal clock signal with the second internal clock signal; and (iv) output control circuitry for synchronizing the at least one internal non-clock signal with the third internal clock signal; a phase difference between the second and third internal clock signals corresponding to the difference between the first and second propagation delays.

A third broad aspect of the invention seeks to provide a system comprising a plurality of semiconductor devices connected in a serial manner and a controller for communicating with the semiconductor devices, the controller being configured to output a clock signal, a control signal and a data signal; each of the plurality of semiconductor devices having: (i) internal circuitry for outputting at least one internal clock signal and at least one internal data/control signal; (ii) data/control output circuitry configured to output at least one output data/control signal from the at least one internal data/control signal and for releasing the at least one output data/control signal towards a next one of the semiconductor devices via at least one output data/control signal line, the at least one output data/control signal having a first dynamic range; and (iii) clock output circuitry configured to provide at least one output clock signal from the at least one internal clock signal and to release the at least one output clock signal towards the next one of the semiconductor devices via at least one output clock signal line, the at least one output clock signal having a second dynamic range different than the first dynamic range.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 shows a system of serially connected memory devices, in accordance with a non-limiting embodiment;

FIG. 2 is a block diagram of a memory device in accordance with a non-limiting embodiment;

FIG. 3 shows timing mismatches due to different voltage level between clocks and other signals;

FIG. 4 is a block diagram conceptually illustrating various functional elements of a clock generator, in accordance with a non-limiting embodiment;

FIG. 5 shows a timing diagram of internal clock generation within the clock generator;

FIGS. 6A, 6B and 6C show different non-limiting examples of a voltage regulator for generating a clock voltage; and

FIG. 7 shows a system of serially connected memory devices, in accordance with a further non-limiting embodiment.

### DETAILED DESCRIPTION

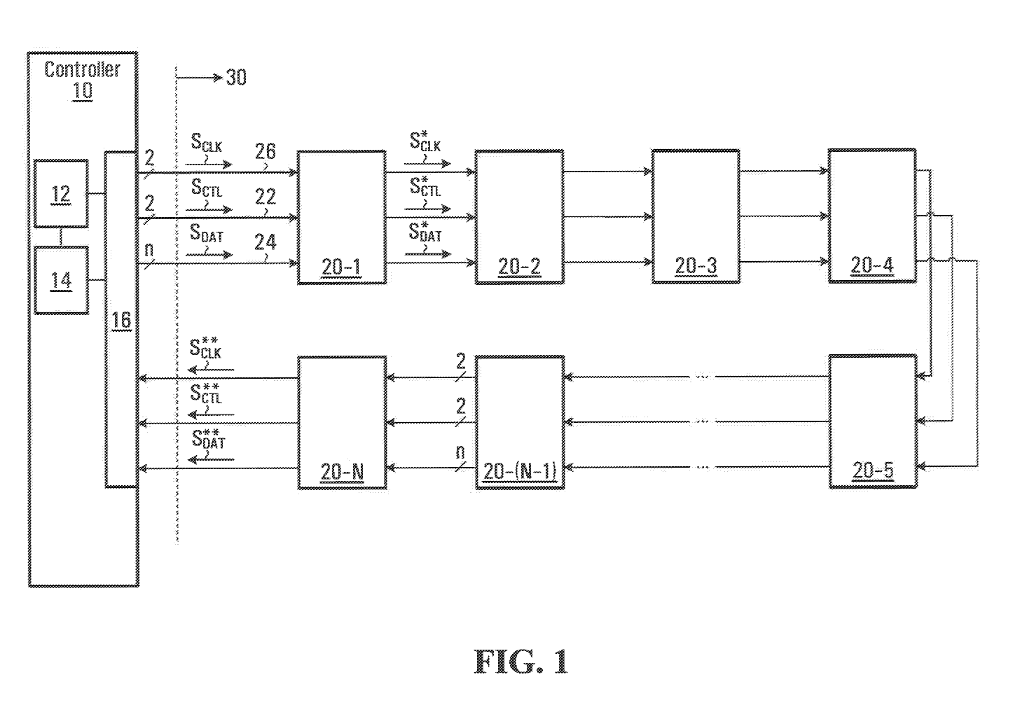

FIG. 1 shows a system comprising a controller 10 and a plurality of devices 20-1, 20-2, 20-(N−1), 20-N interconnected in a ring 30 (also referred to as a serial interconnection or point-to-point interconnection). The devices include a first device 20-1, zero or more intermediate devices 20-2, . . . , 20-(N−1) and a last device 20-N. The last device 20-N is connected back to the controller 10, thus completing the ring 30. It should be appreciated that N, the number of devices in the ring 30, is not particularly limited.

In the illustrated embodiment, each of the devices 20-1, 20-2, . . . , 20-(N−1), 20-N is a memory device and includes a memory (not shown) for writing and reading data. Also in the illustrated embodiment, the controller 10 is a memory controller. However, in other embodiments, each of the devices 20-1, 20-2, . . . , 20-(N−1), 20-N may be any kind of a semiconductor device having or being associated with a memory. Also, the controller 10 may be a device and it may be any kind of a memory controller.

The memory controller 10 comprises a clock producer 12, control logic 14, interface circuitry 16 and other elements that will allow it to perform the functionality described herein. The memory controller 10 is connected (e.g., via a bus) to external circuitry (not shown) such as a processing unit associated with digital electronic equipment (e.g., camera, mobile phone, portable computer, e-book reader, etc).

The memory controller 10 transmits control signals S_{CTL} and data signals S_{DAT} to the first memory device 20-1 over a set of control signal lines 22 and data signal lines 24, respectively. This is done in a source-synchronous manner, namely in synchronism with one or more clock signals S_{CLK} that are transmitted from the memory controller 10 to the first memory device 20-1 over a set of clock signal lines 26. The first memory device 20-1 processes the control signals S_{CTL} and the data signals S_{DAT} (as synchronized by the clock signals S_{CLK}), and transmits a further set of clock signals S_{GLK}*, control signals S^{CTL}* and data signals S_{DAT}* to the next memory device 20-2, and so on, until the last memory device 20-N transmits a final set of clock signals S^{CLK}**, control signals S_{DTL}** and data signals S_{DAT}** back to the memory controller 10. The configuration of FIG. 1 has an increased ability to allow multiple interconnected memory devices 20 to operate at high frequencies, due to the reduced signal loading requirements of each point-to-point link.

The number of control signals S_{CTL} may vary from one implementation to another. For example, in the illustrated non-limiting embodiment, there are two control signals S_{CTL}. The two control signals S_{CTL} include a command/address control signal and a data control signal. In other embodiments (see, for example, U.S. patent application Ser. No. 13/401,087 to Pyeon, filed Feb. 21, 2012), there may be three control signals S_{CTL}) including a command/address control signal, a read data control signal and a write data control signal. In some embodiments, still other signals may be provided (such as a reset signal, a chip enable signal, a write protect signal, etc.), but these are not considered significant for the purposes of understanding the present invention. As for the data signals S_{DAT}, their number is not limited, and can range from 1 to 8 or more. In the interest of generality, the number of data signals S_{DAT} is shown as “n” in FIG. 1. It should be appreciated that the data signals S_{DAT} and the control signals S_{DTL} may be collectively referred to as “data/control” signals.

In order to allow data to be read from and written to the memory devices, the memory controller 10 and the memory devices 20-1, 20-2, . . . , 20-N participate in a communication protocol. The communication protocol involves the issuance of commands by the memory controller 10 and the interpretation of those commands by the memory devices 20-1, 20-2, . . . , 20-N. Accordingly, each of the memory devices 20-1, 20-2, . . . , 20-N includes interface circuitry, an internal memory, an identifier register, control logic circuitry and other elements that will allow it to perform the functionality described herein. Each of the memory devices 20-1, 20-2, . . . , 20-N is identified by an identifier or address that is stored in its identifier register.

The memory controller 10's intent to issue a command destined for a particular memory device (referred to as a “target device”, denoted 20-T, 1≦T≦N) is conveyed by a specific combination of the control signals S_{CTL}, again depending on the implementation. The memory controller 10 then uses the data signals S_{DAT} to convey the target device's identifier as well as other information (such as address information) pertaining to the command. The information pertaining to the command flows from the memory controller 10 around the ring 30 until it reaches the target device 20-T, bypassing any intervening memory devices whose identifiers do not match that of the target device 20-T. In the case of a write operation, the data to be written to the internal memory of the target device 20-T is conveyed by the data signals S_{DAT} and flows from the memory controller 10 around the ring 30 until it reaches the target device 20-T, bypassing any intervening memory devices. In the case of a read operation, data to be read from the internal memory of the target device 20-T is conveyed by the data signals and flows from the target device 20-T around the ring 30 and is provided to the memory controller 10, bypassing any intervening memory devices.

In an embodiment, the control signals S_{CTL} and the data signals S_{DAT} may be single-ended. Thus, the control signals S_{CTL} and the data signals S_{DAT} each range in level between a high voltage V_{DD} and a low voltage V_{SS}. This represents a dynamic range of V_{DD}-V_{SS}, hereinafter referred to as a “regular dynamic range”. The values of V_{DD} and V_{SS} are not particularly limited, and suitable values can be chosen by those of skill in the art.

On the other hand, the clock signals S_{CLK} may be provided as a differential signal pair. In accordance with non-limiting embodiments of the present invention, each of the clock signals S_{CLK} forming part of the differential signal pair can have a reduced dynamic range of V_{CLK}-V_{SS}, where |V_{CTL}-V_{SS}|<|V_{DD}-V_{SS}|. Other than being between V_{SS} and V_{DD}, the value of V_{CLK} is not particularly limited. This can have the advantage of reducing power consumption of the memory system compared to the case where the clock signals would have the same dynamic range (or “voltage swing” or “amplitude”) as the control and data signals. Meanwhile, signal integrity can be maintained due to the differential nature of the clock signals S_{CLK}.

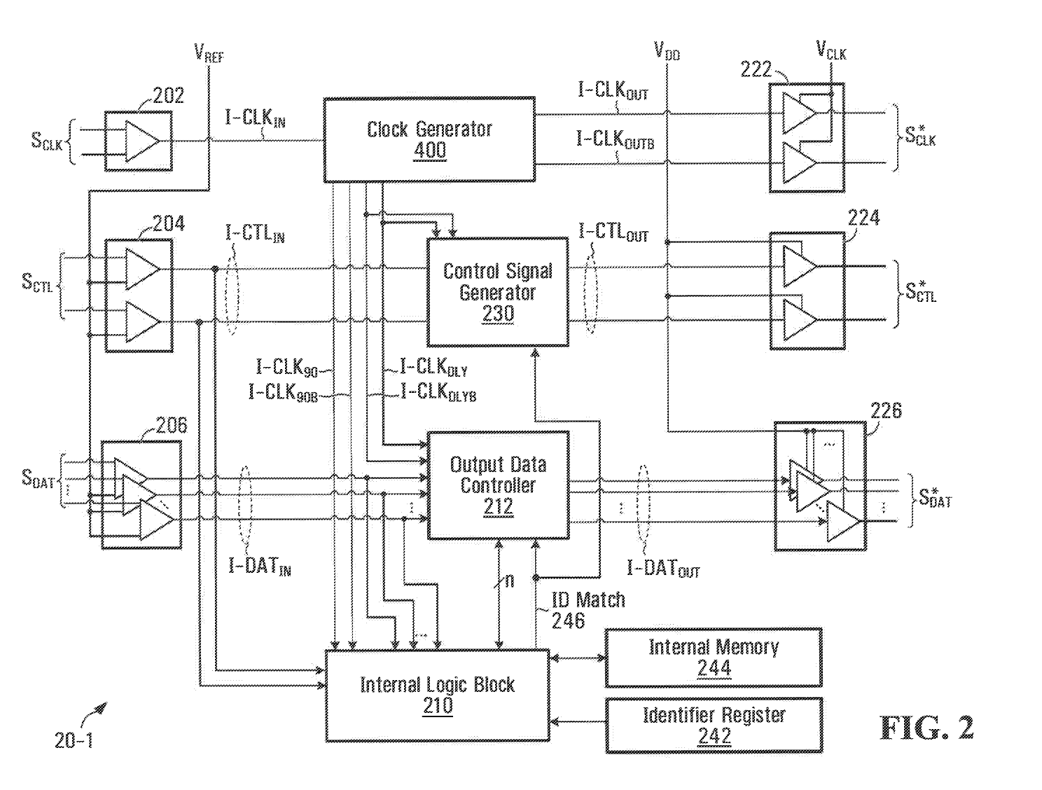

FIG. 2 shows a memory device in accordance with a non-limiting embodiment, including a clock generator and clock output circuitry that outputs a clock signal with a reduced dynamic range. Particularly, FIG. 2 shows the internal structure of the first memory device 20-1. In the first memory device 20-1 shown in FIG. 2, an input clock buffering stage 202, an input control buffering stage 204 and an input data buffering stage 206 form part of input interface circuitry. An output clock buffering stage 222, an output control buffering stage 224 and an output data buffering stage 226 form part of output interface circuitry. An internal logic block 210, an output data controller 212, a control signal generator 230 and a clock generator 400 form part of control logic circuitry. An identifier register 242 for storing an identifier of the first memory device 20-1 and an internal memory 244 for storing data are associated with the first memory device 20-1. The identifier register 242 and the internal memory 244 may be included in or coupled with the first memory device 20-1. The same description can apply to the other memory devices 20-2, . . . , 20-N, which can all be substantially identical to the first memory device 20-1.

Referring to FIGS. 1 and 2, the control signals S_{CTL} and the data signals S_{DAT} provided by the memory controller 10 are received by the input control buffering stage 204 and the input data buffering stage 206, respectively. The input control buffering stage 204 extracts a set of one or more internal input control signals I-CTL_{IN}, which are provided to the internal logic block 210 and to the clock signal generator 230. The input control buffering stage 204 may comprise an arrangement of input buffers, each with a bias voltage of V_{DD}, a first input port fed by one of the control signals S_{CTL} and a second input port provided with a reference voltage V_{REF}, where V_{REF}=½(V_{DD}-V_{SS}). Analogously, the input data buffering stage 206 extracts a set of one or more internal input data signals I-DAT_{IN} and may also comprise an arrangement of input buffers, each with a bias voltage of V_{DD}, a first input port fed by one of the data signals S_{DAT} and a second input port provided with the reference voltage V_{REF}.

In addition, the input clock buffering stage 202 receives the pair of differential clock signals S_{CLK} from the memory controller 10 and extracts an internal input clock signal I-CLK_{IN}. The input clock buffering stage 202 can comprise an input buffer with a bias voltage of V_{DD}, and having its two input ports fed by the pair of differential clock signals S_{CLK}. The internal input clock signal I-CLK_{IN} can thus be a single-ended clock signal having the regular dynamic range (V_{DD}-V_{SS}). In fact, it will be noticed that all the internal input signals I-CTL_{IN}, I-DAT_{IN} and I-CLK_{IN} will have the regular dynamic range (V_{DD}-V_{SS}).

The internal input control signals I-CTL_{IN} and the internal input data signals I-DAT_{IN} are provided to the internal logic block 210. The internal logic block 210 includes or has access to an array of memory cells of the internal memory 244, as well as buffers, registers and other operational circuitry. In addition, an “ID match” signal line 246 is provided from the internal logic block 210 to the output data controller 212 and to the control signal generator 230. The ID match signal line 246 can be enabled or not enabled. When a command identifying a target device is received, the internal logic block 210 determines whether the identifier of the target device matches the identifier stored in the identifier register 242. In the case of a match, the ID match signal line 246 is enabled, and in the case of no match, the ID match signal line 246 is not enabled.

The internal logic block 210 can perform access operations. One of the access operations can include a data write operation based on the internal input control signals I-CTL_{IN} and the internal input data signals I-DAT_{IN}. Another one of the access operations can include a data read operation based on the internal input control signals I-CTL_{IN}. Operation of the internal logic block 210 is synchronized by a pair of complementary clock signals I-CLK₉₀, I-CLK_{90B} (hereinafter “internal pipeline clock signals”) provided by the clock generator 400, which will be described later. The internal pipeline clock signals I-CLK₉₀, I-CLK_{90B} are phase shifted relative to the data signals S_{DAT} by 90 and −90 degrees, respectively, which allows proper latching of data by the internal logic block 210, assuming of course, that an edge-aligned relationship exists between the clock signals S_{DLK}, the control signals S_{DTL} and the data signals S_{DAT} at the input of the first memory device 20-1.

It is recalled that the memory device 20-1 may or may not be the target device for an access operation issued by the memory controller 10. The identity of the target device, as well as the nature of the access operation (e.g., data read or data write), can influence operation of the output data controller 212 and the control signal generator 230, as will now be described. It should be appreciated that operation of the output data controller 212 and the control signal generator 230 is synchronized by a pair of complementary clock signals I-CLK_{DLY}, I-CLK_{DLYB} (hereinafter “delayed clock signals”) provided by the clock generator 400, which will be described later.

Case 1: the memory device 20-1 is the target device and the access operation is a data read.
Having recognized the identifier of the target device as being the identifier of the memory device 20-1, the internal logic block 210 enables the ID match signal line 246 provided to the output data controller 212 and to the control signal generator 230. Furthermore, because the access operation is a data read, the internal logic block 210 provides read data from its memory array of the internal memory 244 to the output data controller 212. The output data controller 212 produces a set of internal output data signals I-DAT_{OUT} based on the read data provided by the internal logic block 210. In addition, the control signal generator 230 produces a specific combination of internal output control signals I-CTL_{OUT} in order to indicate the presence of a valid data signal being output from the memory device 20-1.

Case 2: the memory device 20-1 is the target device and the access operation is a data write.
Again, having recognized the identifier of the target device as being the identifier of the memory device 20-1, the internal logic block 210 enables the ID match signal line 246 provided to the output data controller 212 and to the control signal generator 230. Furthermore, because the access operation is a data write, the output data controller 212 provides the internal output data signals I-DAT_{OUT}, based on “static” data read from the internal memory 244, so that the output data from the memory device 20-1 is truncated. In addition, the control signal generator 230 may suppress the internal output control signals I-CTL_{OUT}: as there is no need to propagate the write control signal and write data to the next memory device 20-2.

Case 3: the memory device 20-1 is not the target device.
Not having recognized the identifier of the target device as being the identifier of the memory device 20-1, the internal logic block 210 does not enable the ID match signal line 246 provided to the output data controller 212 and to the control signal generator 230. Accordingly, the memory device 20-1 is not the target device and therefore simply passes any received information to the next memory device 20-2. Specifically, the internal input data signals I-DAT_{IN} are passed to the output data controller 212, which transfers the information onto the internal output data signals I-DAT_{OUT}. In addition, the control signal generator 230 transfers the information on the internal input control signals I-CTL_{IN} over to the internal output control signals I-CTL_{OUT}.

The internal output data signals I-DAT_{OUT} are fed to the output data buffering stage 226, which produces the set of data signals S_{DAT}* that are provided to the next memory device 20-2. It should be remarked that the internal output data signals I-DAT_{OUT} entering the output data buffering stage 226 have the regular dynamic range (V_{DD}-V_{SS}). In addition, it is intended that the data signals S_{DAT}* provided to the next memory device 20-2 have the regular dynamic range (V_{DD}-V_{SS}). To this end, the output data buffering stage 226 can comprise a set of output buffers with a bias voltage of V_{DD}. The resulting data signals S_{DAT}^{*} (having the regular dynamic range of V_{DD}-V_{SS}) are transmitted to the next memory device 20-2 over a set of data signal lines.

The internal output control signals I-CTL_{OUT} are fed to the output control buffering stage 224, which produces the set of control signals S_{CTL}* that are provided to the next memory device 20-2. It should be remarked that the internal output control signals I-CTL_{OUT} entering the output control buffering stage 224 have the regular dynamic range (V_{DD}-V_{SS}). In addition, it is intended that the control signals S^{CTL}* provided to the next memory device 20-2 have the regular dynamic range (V_{DD}-V_{SS}). To this end, the output control buffering stage 224 can comprise a set of output buffers with a bias voltage of V_{DD}. The resulting control signals S_{CTL}* (having the regular dynamic range of V_{DD}-V_{SS}) are transmitted to the next memory device 20-2 over a set of control signal lines.

The clock generator 400 will now be described. Generally speaking, the clock generator 400 processes the internal input clock signal I-CLK_{IN} and generates three pairs of complementary clock signals. Firstly, the clock generator 400 generates the aforementioned internal pipeline clock signals I-CLK₉₀, I-CLK_{90B}, which are 90 and −90 degrees out of phase with the received control and data signals S_{CTL}, S_{DAT} and are used to synchronize operation of the internal logic block 210. Secondly, the clock generator 400 generates the aforementioned delayed clock signals I-CLK_{DLY}, I-CLK_{DLYB}, which are used to synchronize the output data controller 212 and the control signal generator 230.

In addition, the clock generator 400 generates a pair of internal output clock signals I-CLK_{OUT}, I-CLK_{OUTB}, which are fed to the output clock buffering stage 222. The internal output clock signals I-CLK_{OUT}, I-CLK_{OUTB} have the regular dynamic range (V_{DD}-V_{SS}). However, since it is intended that the clock signals S_{CLK}* to be sent to the next memory device 20-2 have the reduced dynamic range (V_{CLK}-V_{SS}), the output clock buffering stage 222 can comprise a pair of output buffers with a bias voltage of V_{CLK}. The resulting clock signals S_{CLK}* (having the reduced dynamic range of V_{CLK}-V_{SS}) are transmitted to the next memory device 20-2 over a set of data signal lines. The reduced dynamic range of the clock signals S_{CLK}* enables power consumption savings at the system level.

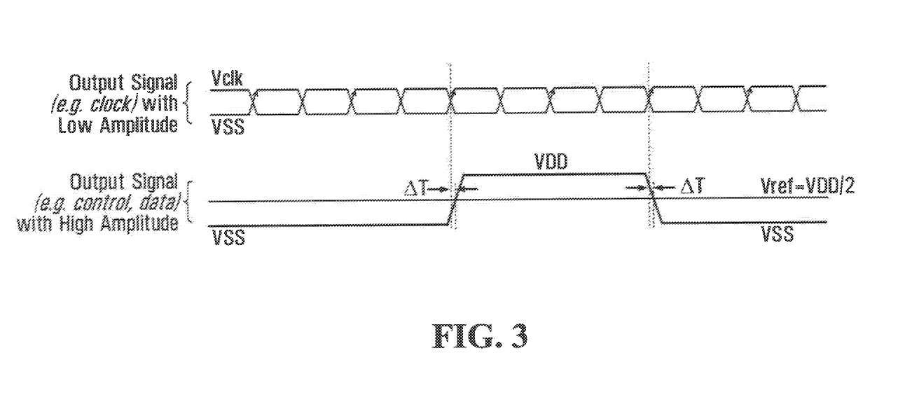

Because the output clock buffering stage 222 functions differently from the output control or data buffering stages 224, 226 (i.e., it provides dynamic range reduction as a result of being biased to V_{CLK} as opposed to V_{DD}), there may be differences in the physical and electrical properties of the output buffers in the output clock buffering stage 222 relative to the output buffers in the output control or data buffering stages 224, 226. For example, to counter performance degradations due to the lower voltage level (V_{CLK}<V_{DD}), the output buffers in the output clock buffering stage 222 may need to have bigger PMOS/NMOS drivers to deliver the same amount of driving capability as the output buffers in the other stages 224, 226. These physical and electrical variations may, in turn, lead to a difference in the time it takes for the internal output clock signals I-CLK_{OUT}, I-CLK_{OUTB} to transit the output buffers in the output clock buffering stage 222 when compared to the time it takes for the control or data signals I-CTL_{OUT}, I-DAT_{OUT} to transit the output buffers in the output control or data buffering stages 224, 226, respectively. This relative difference in propagation times, referred to as a skew parameter, is denoted ΔT and is illustrated in FIG. 3. It will be appreciated that larger values of ΔT, if left uncompensated, will have a greater negative impact on performance at high frequencies.

However, ΔT can be compensated for by causing the internal output clock signals I-CLK_{OUT}, I-CLK_{OUTB} to be delayed even more than the delayed clock signals I-CLK_{DLY}, I-CLK_{DLYB}, as will be described below. It is not required that the clock generator 400 set this relative delay equal to precisely the skew parameter ΔT. However, the closer this imposed delay approaches ΔT, the greater the neutralizing effect and the better the alignment between the clock signals S_{CLK}* and the non-clock signals (namely, the control signals S_{CTL}* and the data signals S_{DAT}*) at the output of the first memory device 20-1.

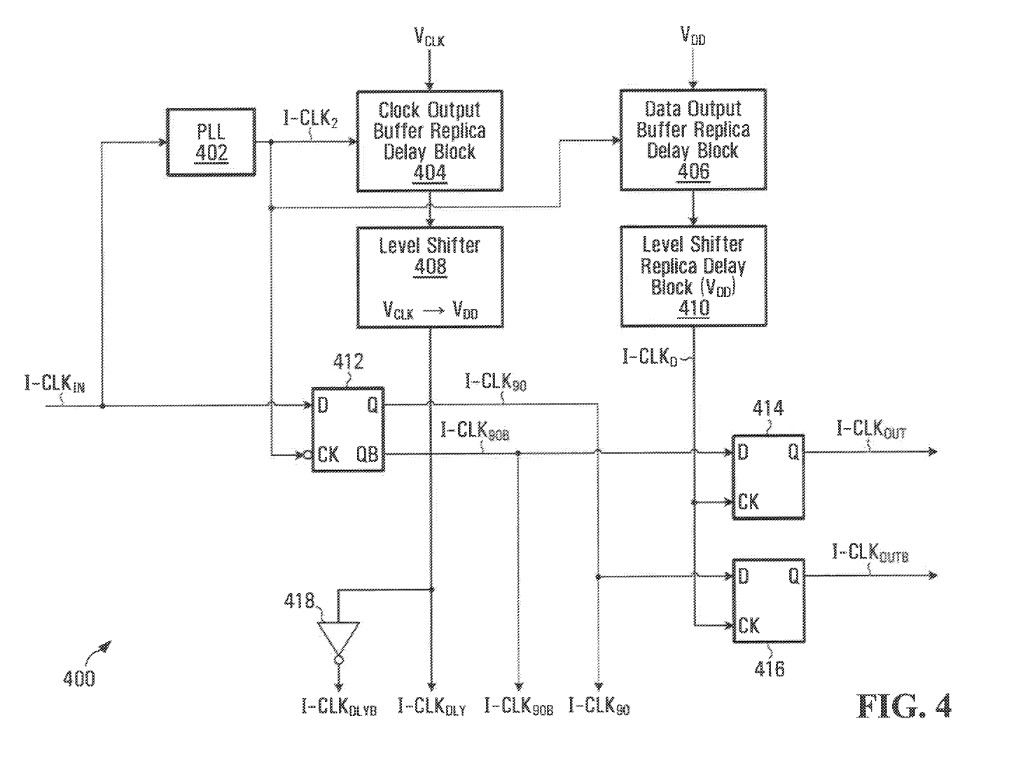

Accordingly, generation of the internal pipeline clock signals I-CLK₉₀, I-CLK_{90B}, the delayed clock signals I-CLK_{DLY}, I-CLK_{DLYB} and the internal output clock signals I-CLK_{OUT}, I-CLK_{OUTB} is now described in greater detail with reference to FIG. 4, which illustrates a conceptual block diagram of the clock generator 400 in accordance with a non-limiting embodiment. As shown in FIG. 4, the clock generator 400 comprises a phase locked loop (PLL) 402, a clock output buffer replica delay block 404, a data output buffer replica delay block 406, a level shifter 408, a level shifter replica delay block 410, a falling-edge-triggered D-flip-flop 412, two rising-edge-triggered D-flip-flops 414, 416 and an inverter 418. The flip-flops 412, 414, 416 each have a data input port (D), a clock input port (CK), a data output port (Q) and, optionally, a complementary data output port (QB). The clock generator 400 also has access to voltage sources at V_{CLK} and V_{DD}.

Referring to FIGS. 2 and 4, in operation, the internal input clock signal I-CLK_{IN} is fed to the PLL 402 and to the data input port of the falling-edge-triggered D-flip-flop 412. The PLL 402 is configured to output an accelerated clock signal I-CLK₂ at twice the frequency of the internal input clock signal I-CLK₁N. The accelerated clock signal I-CLK₂ is fed to the clock input port of the falling-edge-triggered D-flip-flop 412. Thus, the falling-edge-triggered D-flip-flop 412 produces, at its data output port, a clock signal I-CLK₉₀ that has the same frequency as the internal input clock signal I-CLK_{IN} but is shifted relative thereto by 90 degrees. Similarly, the complementary data output port of the falling-edge-triggered D-flip-flop 412 produces a clock signal I-CLK_{90B} that has the same frequency as the internal input clock signal I-CLK_{IN} but is shifted relative thereto by −90 degrees. These two clock signals I-CLK₉₀, I-CLK_{90B} (which are complementary to one another) are the aforementioned “internal pipeline clock signals”, which are used to synchronize data capture and other pipeline operations executed by the internal logic block 210. In addition, the internal pipeline clock signals I-CLK₉₀, I-CLK_{90B} are used as the foundation for the internal output clock signals I-CLK_{OUT}, I-CLK_{OUTB}. However, rather than being provided directly to the output clock buffering stage 222, the clock signals I-CLK₉₀, I-CLK_{90B} are provided to the respective data input ports of the two rising-edge-triggered D-flip-flops 414, 416. The rising-edge-triggered D-flip-flops 414, 416 are clocked by the aforementioned delayed clock signal I-CLK_{DLY} (discussed below in further detail), so as to provide, at their respective data output ports, the pair of internal output clock signals I-CLK_{OUT}, I-CLK_{OUTB}.

Returning now to the PLL 402, the accelerated clock signal I-CLK₂ is also fed to the clock output buffer replica delay block 404 and to the data output buffer replica delay block 406. Each of these delay blocks 404, 406 applies a delay that emulates the respective buffer that it designates.

Thus, the clock output buffer replica delay block 404 applies a delay that corresponds to the transit time through the output clock buffering stage 222. To this end, a voltage at V_{CLK} is provided in order to facilitate emulation of the appropriate delay. For example, the clock output buffer replica delay block 404 may comprise an output buffer biased to V_{CLK}, just like the output buffers in the output clock buffering stage 222. In this case, the output of the clock output buffer replica delay block 404 will have a reduced voltage swing (V_{CLK}-V_{SS}), and passing this signal through the level shifter 408 (biased to V_{DD}) can produce the delayed clock signal I-CLK_{DLY} with the regular voltage swing (V_{DD}-V_{SS}). The inverter 418 then produces the complementary delayed clock signal I-CLK_{DLYB}.

Therefore, when the control signal generator 230 and the output data controller 212 are clocked by the delayed clock signals I-CLK_{DLY}, I-CLK_{DLYB}, this will result in the internal output control signals I-CTL_{OUT} and the internal output data signals I-DAT_{OUT} having transitions that will be delayed (relative to the internal input clock signal I-CLK_{IN}) by the total of the delay imposed by the clock output buffer replica delay block 404 and the level shifter 408.

In an analogous fashion, the data output buffer replica delay block 406 applies a delay that corresponds to the transit time through the output control buffering stage 224 or the output data buffering stage 226. To this end, a voltage at V_{DD} is provided in order to facilitate emulation of the appropriate delay. For example, the data output buffer replica delay block 406 may comprise an output buffer biased to V_{DD}, just like the output buffers in the output control buffering stage 224 and/or the output data buffering stage 226. Here, a level shifter would not be needed because the output of the data output buffer replica delay block 406 would have the regular voltage swing (V_{DD}-V_{SS}). However, the level shifter 408 at the output of the clock output buffer replica delay block 404 does introduce a delay. Accordingly, as a compensatory measure, the level shifter replica delay block 410 applies a delay that emulates the delay applied by the level shifter 408. For example, a level shifter identical to the level shifter 408 may be utilized, but whose practical purpose is to apply the same delay as the level shifter 408, under a variety of temperature and other conditions.

The output of the level shifter replica delay block 410 is a delayed clock signal I-CLK_{D}, which is fed to the clock input port of each of the rising-edge-triggered D-flip-flops 414, 416. It will be recalled that the data input ports of the rising-edge-triggered D-flip-flops 414, 416 are fed with the internal pipeline clock signals I-CLK₉₀, I-CLK_{90B}, which are, respectively, 90 and −90 degrees out of phase with the internal input clock signal I-CLK_{IN}. Therefore, the data output ports of the rising-edge-triggered D-flip-flops 414, 416 will contain the total of the delay imposed by the data output buffer replica delay block 406 and the level shifter replica delay block 410 along with PLL path time delay. The data output ports of the rising-edge-triggered D-flip-flops 414, 416 carry the internal output clock signals I-CLK_{OUT}, I-CLK_{OUTB}.

Since the delays imposed by the level shifter delay replica delay block 410 is the same (or virtually the same) as the delay imposed by the level shifter 408 itself, it will be apparent that the internal output clock signals I-CLK_{OUT}, I-CLK_{OUTB} contain the delay of the clock output buffer replica delay block 404 and the level shifter 408. Moreover, the internal output clock signals I-CLK_{OUT}, I-CLK_{OUTB} are then even further delayed by the delay imposed by the output clock buffering stage 222, whereas the data and control signals clocked by the delayed clock signals I-CLK_{DLY}, I-CLK_{DLYB} are then even further delayed by the delay imposed by the output data and control buffering stages 226, 224. Therefore, if the delay imposed by the data output buffer replica delay block 406 can be designed to match the delay imposed by the output data and control buffering stages 226, 224, and if the delay imposed by the clock output buffer replica delay block 404 can be designed to match the delay imposed by the output clock buffering stage 222, then this will minimize the phase offset between the clock signals S^{CLK*} output by the output clock buffering stage 222 and the data and control signals S_{DAT}*, S_{CTL}* output by the output data and control buffering stages 226, 224, respectively. That is to say, the clock signals S_{CLK}*, data signals S_{DAT}* and control signals S^{CLK}* will be aligned with one another as they exit the first memory device 20-1, yet the clock signals S^{CLK}* will have a smaller amplitude and therefore consume less power as they travel to the second memory device 20-2.

In an alternative embodiment, rather than including a separate level shifter replica delay block 410, it is envisaged that the data output buffer replica delay block 406 can be designed to compensate for both the delay applied by the output buffers in the output clock buffering stage 222 and the level shifter 408 in the clock generator 400.

Also, it should be appreciated that the PLL 402 need not be integrated within the clock generator 400, but instead may be disposed separately from the clock generator 400.

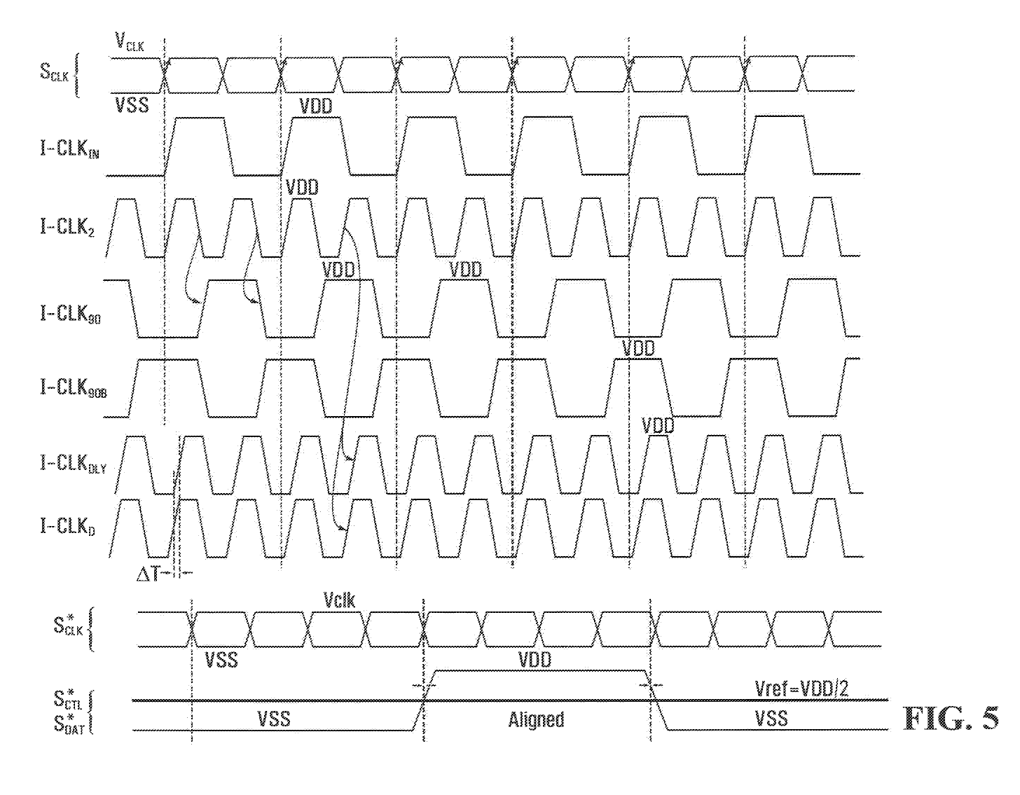

FIG. 5 shows a timing diagram in which the various clock signals described above are shown. It is noted towards the bottom of FIG. 5 that the edges of the clock signals S^{CLK}* are aligned with the edges of the control and data signals S_{CTL}*, S_{DAT}* provided at the output of the first memory device 20-1. This is due to the fact that the difference between the delay provided by the clock output buffering stage 222 and the delay provided by the non-clock output buffering stages 224, 226 (arising from use of a lower voltage V_{CLK}<V_{DD} to bias the clock output buffering stage 222) has been compensated by causing a substantially equal but opposite delay to exist between the signals that enter the output buffering stage 222 and the signals that enter the non-clock output buffering stages 224, 226.

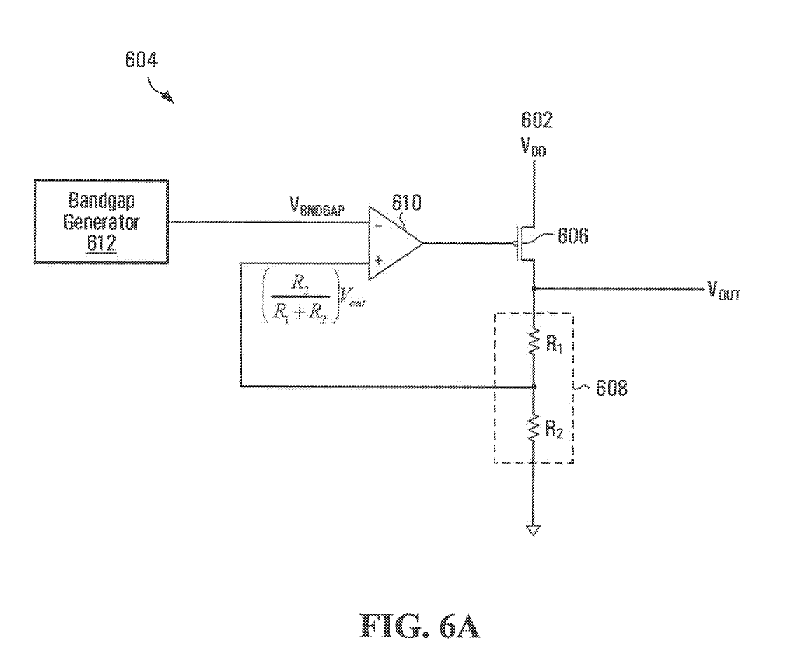

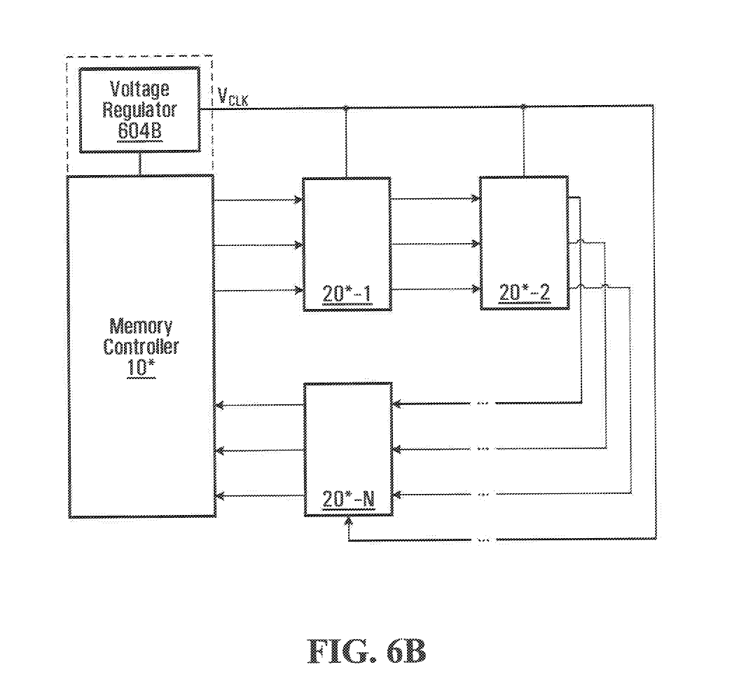

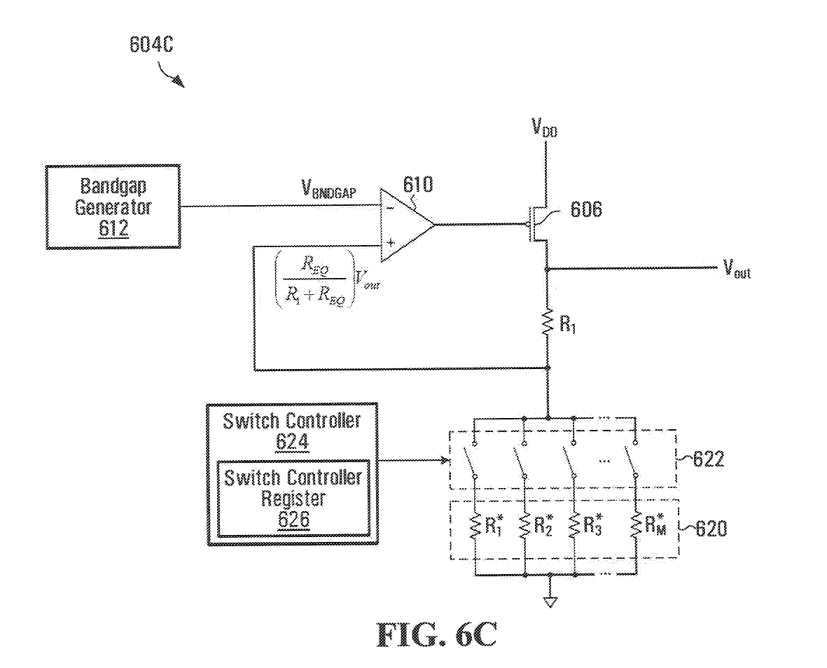

Three non-limiting ways of generating a voltage at V_{CLK} will now be described, with the understanding that other techniques will become apparent to those of skill in the art. In a first example, shown in FIG. 6A, a voltage at V_{CLK} is provided from a power supply 602 at V_{DD} by means of a voltage regulator 604 integrated within the first memory device 201. Specifically, the voltage regulator 604 comprises a driving transistor 606, which acts as a variable resistor to regulate the output voltage V_{OUT}. In a non-limiting embodiment, the transistor 606 has two current-carrying electrodes and a control port. In the illustrated non limiting embodiment, the transistor 606 is a PMOS transistor whose current-carrying electrodes are a source and a drain, and whose control port is a gate. However, it should be appreciated that other transistor types may be used.

The source and drain of the transistor 606 are connected between the power supply 602 at V_{DD} and a resistive divider 608 comprising resistors R₁ and R₂. The gate of the transistor 606 is connected to the output port of an operational amplifier 610. In order to provide a constant output voltage V_{OUT}, a feedback loop is established with the operational amplifier 610. That is to say, the operational amplifier 610 compares a portion of the output voltage V_{OUT} taken from the resistive divider 608 (in this case (R₂/(R₁+R₂))*V_{OUT}) to a predetermined “bandgap” reference voltage V_{BNDGAP} provided by a bandgap generator 612. The difference is amplified by the operational amplifier 610 and applied to the gate of the transistor 606. The voltage regulator 604 therefore strives to make (R₂/(R₁+R₂))*V_{OUT} equal to V_{BNDGAP}. Therefore, if the bandgap reference voltage V_{BNDGAP} is set to (R₂/(R₁+R₂))*V_{CLK} for some desired value of V_{CLK}, then the voltage regulator 604 will strive to keep the output voltage V_{OUT} equal to the desired value of V_{CLK}. The bandgap generator 612 may include temperature compensation and other measures for maintaining V_{BNDGAP} at a consistent predetermined level.

In a second example, shown in FIG. 6B, a voltage at V_{CLK} is provided externally without requiring a voltage regulator to be integrated within the memory device. Specifically, there is provided a voltage regulator 604B similar to the voltage regulator 604 of FIG. 6A. However, the voltage regulator 604B in FIG. 6B is external, and may be located within the memory controller 10* or elsewhere in the memory system. The memory devices 20*-1, 20*-2, . . . , 20*-N include a separate port for receiving the output of the voltage regulator 604B, which is at V_{CLK}. As such, V_{CLK} may be made available to all the memory devices 20*-1, 20*-2, . . . , 20*-N in a parallel fashion, in which case there needs to be an ability to drive the required amount of current to the plurality of memory devices 20*-1, 20*-2, . . . , 20*-N. A second stage voltage regulator may be provided for this purpose. Alternatively, the memory controller 10* may implement a dedicated voltage regulator for each memory device.

In the example of FIG. 6B, V_{CLK} can be kept stable and, moreover, can be easily changed for all memory devices 20*-1, 20*-2, . . . , 20*-N as a function of system requirements. In particular, the voltage regulator 604B can be manipulated by the memory controller 10* so that, at any given time, the memory controller 10* can change the value of V_{CLK} based on signal integrity and power consumption monitoring by the memory controller 10*.

In a third example, shown in FIG. 6C, the value of V_{CLK} is controlled using a voltage regulator 604C internal to each memory device. This is a flexible way to maintain good signal integrity and low power consumption monitoring by the memory controller 10. The voltage regulator 604C is similar to the voltage regulator 604 of FIG. 6A, except that resistor R₂ has been replaced with a resistor bank 620, a plurality of switches 622 and a switch controller 624. The resistor bank 620 includes a plurality of resistors R*ⱼ, 1≦j≦M, placed in parallel, where M>1 and is not particularly limited. Each of the resistors R*ⱼ in the resistor bank 620 is connected in series with one of the switches 622, all of which are controlled by the switch controller 624. The switch controller 624 can close one or more of the switches 622, based on the value of a switch control register 626. The switch control register 626 can be written to by the memory controller 10 using a register write command.

The resistors R*ⱼ may have different resistances or they may all have the same resistance. By varying which of the switches 622 to close, the equivalent resistance of the resistor bank 620, denoted R_{EQ}, can be controlled. Since the operational amplifier 610 tries to make V_{OUT}*R_{EQ}/(R₁+R_{EQ}) equal to V_{BNDGAP}, knowledge of V_{BNDGAP} and R₁ allows selection of R_{EQ} that yields any desired V_{OUT}. For example, if it is desired to make V_{OUT} equal to V_{CLK} for some desired value of V_{CLK}, then one can set R_{EQ} equal to R₁*V_{BNDGAP}/(V_{CLK}-V_{BNDGAP}). One can then identify the desired combination of resistors R*ⱼ whose equivalent resistance in parallel yields R_{EQ}.

As such, the memory system may be able to provide reduced power consumption while maintaining signal integrity.

The presently proposed technique can be applied to any kind of solid state memory system such as NAND Flash electrically erasable programmable read-only memory (EEPROM), NOR Flash EEPROM, AND Flash EEPROM, DiNOR Flash EEPROM, Serial Flash EEPROM, dynamic random access memory (DRAM), static random access memory (SRAM), read-only memory (ROM), electrically programmable read-only memory (EPROM), ferroelectric random access memory (FeRAM or FRAM), magnetoresistive random access memory (MRAM) and phase change random access memory (PRAM or PCRAM), to name a few non-limiting possibilities.

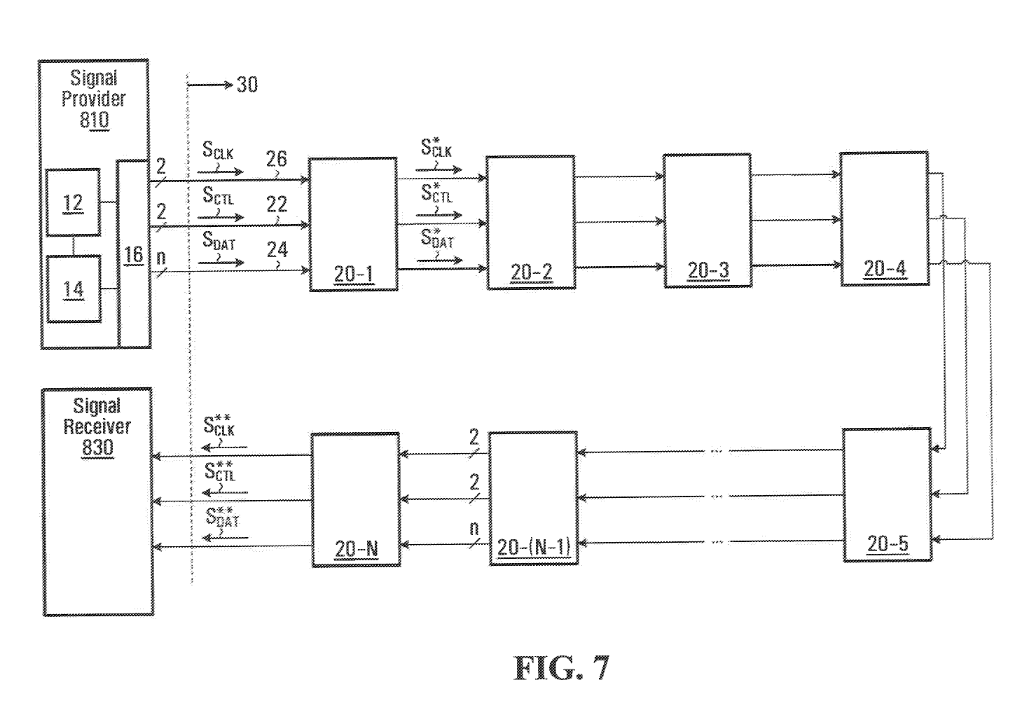

FIG. 7 shows another embodiment of a system of serially connected devices 20-1, 20-2, . . . , 20-N. In this embodiment, controller functions are assigned to a signal provider 810 and a signal receiver 830. In this embodiment, the signal provider 810 provides the signals clock signals S_{CLK}, the control signals S_{CTL} and the data signals S_{DAT} to the first device 20-1. The signals are propagated through the memory devices. The last device 20-N provides signals to the signal receiver 830.

It should also be noted that in some embodiments, the devices in the ring 30 need not be memory devices. For example, the devices can be communication control chips or logic-based chips, to name a few non-limiting possibilities. Thus, embodiments of the present invention can assist in reducing power consumption wherever a serial connection of semiconductor devices may appear.

Although the above description has focused on the embodiment where it is desirable for the clock signals to have a narrower dynamic range than the non-clock signals, it is possible to envisage situations where it may be desirable for the clock signals to have a wider dynamic range than the non-clock signals. It will be appreciated that the above teachings can be applied to this latter scenario without any significant modifications.

In the embodiments described above, the device elements and circuits are connected to each other as shown in the figures for the sake of simplicity. In practical applications these device elements, circuits, etc., may be connected directly to each other or indirectly through other device elements, circuits, etc. Thus, in an actual configuration, the device elements, circuits, etc., are coupled either directly or indirectly with each other.

The above-described embodiments of the present invention are intended to be examples only. Alterations, modifications and variations may be effected to the particular embodiments by those of skill in the art without departing from the scope of the invention, which is defined solely by the claims appended hereto.

What is claimed is:

1. A semiconductor device, comprising:
internal circuitry for outputting at least one internal clock signal and at least one internal data/control signal;
data/control output circuitry configured to output at least one output data/control signal from the at least one internal data/control signal and for releasing the at least one output data/control signal towards a next device in a chain of semiconductor devices via at least one output data/control signal line, the at least one output data/control signal having a first dynamic range; and
clock output circuitry configured to provide at least one output clock signal from the at least one internal clock signal and to release the at least one output clock signal towards the next device via at least one output clock signal line, the at least one output clock signal having a second dynamic range different than the first dynamic range.

2. The semiconductor device of claim 1, wherein the second dynamic range is narrower than the first dynamic range.

3. The semiconductor device of claim 1, wherein the at least one internal clock signal and the at least one internal data/control signal have the same dynamic range.

4. The semiconductor device of claim 1, wherein the at least one output data/control signal includes at least one of a data signal and a control signal.

5. The semiconductor device of claim 1, wherein the internal circuitry comprises an internal logic block comprising memory and circuitry for writing to and reading from the memory on a basis of information conveyed in at least one input data/control signal received from a previous device in the chain.

6. The semiconductor device of claim 5, wherein the at least one internal clock signal is at least one first internal clock signal, operation of the internal logic block being synchronized by at least one second internal clock signal derived from at least one input clock signal received from a previous device in the chain.

7. The semiconductor device of claim 6, wherein the internal circuitry further comprises a clock producer configured for deriving the at least one second internal clock signal from the at least one input clock signal.

8. The semiconductor device of claim 7, wherein the clock producer is further configured for producing the at least one first internal clock signal from the at least one input clock signal.

9. The semiconductor device of claim 8, wherein the internal circuitry further comprises data/control output control circuitry for outputting the at least one internal data/control signal from the at least one input data/control signal and from read data supplied by the internal logic block.

10. The semiconductor device of claim 9, wherein operation of the data/control output control circuitry is synchronized by at least one third internal clock signal.

11. The semiconductor device of claim 10, wherein the clock producer is further configured for producing the at least one third internal clock signal from the at least one input clock signal.

12. The semiconductor device of claim 11, wherein the clock producer is configured for producing the at least one first internal clock signal by synchronizing the at least one second internal clock signal with a delayed clock signal.

13. The semiconductor device of claim 12, wherein the at least one input clock signal comprises a pair of differential clock signals, the device further comprising an input stage for producing a single-ended input clock signal from the pair of differential clock signals.

14. The semiconductor device of claim 13, wherein the at least one input data/control signal comprises a plurality of single-ended data/control signals.

15. The semiconductor device of claim 13, wherein the clock producer comprises:
circuitry for accelerating the frequency of the single-ended input clock signal, thereby to produce an accelerated clock signal;
a first delay replica element for delaying the accelerated clock signal in order to produce the delayed clock signal; and
a second delay replica element for delaying the accelerated clock signal in order to produce the at least one third clock signal.

16. The semiconductor device of claim 15, wherein the circuitry for accelerating the frequency of the input clock signal comprises a phase locked loop for doubling the frequency of the at least one input clock signal.

17. The semiconductor device of claim 15, wherein the delay imposed by the first delay element is an amount of delay associated with passage of the at least one first internal clock signal through the data/control output circuitry, and wherein the delay imposed by the second delay replica element is an amount of delay associated with passage of the at least one data/control signal through the clock output circuitry.

18. The semiconductor device of claim 15, wherein the first delay replica element includes a first output buffer having properties corresponding to those of the data/control output circuitry, and wherein the second delay replica element includes a second output buffer having properties corresponding to those of the clock output circuitry.

19. The semiconductor device of claim 15, wherein the second output buffer produces an intermediate signal having the second dynamic range, and wherein the clock producer further comprises a level shifter fed by the second output buffer to cause the at least one third signal to have the first dynamic range.

20. The semiconductor device of claim 19, wherein the first output buffer produces an intermediate signal having the first dynamic range, and wherein the clock producer further comprises a level shifter replica delay element fed by the first output buffer, the level shifter replica delay element imposing the same delay as the level shifter connected to the second output buffer.

21. The semiconductor device of claim 20, wherein the level shifter replica delay element comprises a level shifter.

22. The semiconductor device of claim 15, wherein the at least one third internal clock signal comprises a pair of clock signals, wherein the clock producer further comprises phase shift circuitry for shifting the phase of the single-ended input clock signal by 90 degrees in order to produce one of the third internal clock signals and for shifting the phase of the single-ended input clock signal by −90 degrees in order to produce the other of the third internal clock signals.

23. The semiconductor device of claim 22, wherein the phase shift circuitry comprises a falling edge-triggered D-flip-flop having a data input port, a control input port and a pair of output ports, wherein the single-ended input clock signal is provided to the data input port, wherein the accelerated clock signal is provided to the clock input port and wherein the third internal clock signals are taken from the pair of output ports.

24. The semiconductor device of claim 12, wherein the clock producer is configured to delay release of the at least one third clock signal and the delayed clock signal such that the cumulative amount of time by which the third clock signal is delayed minus the cumulative amount of time by which the delayed clock signal is delayed corresponds to the amount of delay associated with passage of the at least one data/control signal through the data/control output circuitry minus the amount of delay associated with passage of the at least one first internal clock signal through the clock output circuitry.

25. The semiconductor device of claim 1, wherein the at least one output data/control signal and the at least one output clock signal are time aligned.

26. The semiconductor device of claim 1, wherein the at least one first internal clock signal is phase shifted relative to the at least one second internal clock signal.

27. The semiconductor device of claim 2, wherein the data/control output circuitry is biased to a first voltage that defines an upper bound of the first dynamic range and wherein the clock output circuitry is biased to a second voltage that defines an upper bound of the second dynamic range.

28. The semiconductor device of claim 27, wherein the first voltage is greater than the second voltage.

29. The semiconductor device of claim 27, wherein the second voltage is provided by a voltage regulator.

30. The semiconductor device of claim 29, wherein the first voltage is invariable.

31. The semiconductor device of claim 29, wherein the first voltage can be changed by supplying a control signal to the voltage regulator.

32. The semiconductor device of claim 29, wherein the voltage regulator comprises:
a transistor having a pair of current-carrying electrodes and a control port, one of the current-carrying electrodes being connected to a power supply;
an operational amplifier having a first input port, a second input port and an output port, the output port of the operational amplifier being connected to the control port of the transistor;
a bandgap voltage source connected to the first input port of the operational amplifier;
a resistive divider connected between the other of the current-carrying electrodes of the transistor and the second input port of the operational amplifier, the resistive divider comprising a first resistive portion connected to a second resistive portion at a node;
wherein the first voltage is taken at the node of the resistive divider.

33. The semiconductor device of claim 32, wherein the power supply is maintained at the first voltage.

34. The semiconductor device of claim 33, wherein the first and second resistive portions provide a fixed resistance or a variable resistance.

35. The semiconductor device of claim 34, wherein the at least one of the first and second resistive portions comprises a plurality of resistors connected to respective switches and placed in parallel, wherein control of the switches provides control of the variable resistance.

36. The semiconductor device of claim 35, wherein control of the switches is provided by a command received from a controller.

37. The semiconductor device of claim 36, wherein the command is conveyed by the at least one data/control signal.

38. The semiconductor device of claim 1 being a memory device.

39. A semiconductor device, comprising:
clock output circuitry for outputting at least one output clock signal from at least one first internal clock signal, the clock output circuitry providing a first propagation delay therethrough;
non-clock output circuitry for outputting at least one output non-clock signal from at least one internal non-clock signal, the non-clock output circuitry providing a second propagation delay therethrough;
a clock producer for producing a second internal clock signal and a third internal clock signal, the clock producer comprising circuitry for synchronizing the first internal clock signal with the second internal clock signal; and
output control circuitry for synchronizing the at least one internal non-clock signal with the third internal clock signal,
a phase difference between the second and third internal clock signals corresponding to the difference between the first and second propagation delays.

40. A system comprising a plurality of semiconductor devices connected in a serial manner and a controller for communicating with the semiconductor devices,
the controller being configured to output a clock signal, a control signal and a data signal;
each of the plurality of semiconductor devices having:
internal circuitry for outputting at least one internal clock signal and at least one internal data/control signal;
data/control output circuitry configured to output at least one output data/control signal from the at least one internal data/control signal and for releasing the at least one output data/control signal towards a next one of the semiconductor devices via at least one output data/control signal line, the at least one output data/control signal having a first dynamic range; and
clock output circuitry configured to provide at least one output clock signal from the at least one internal clock signal and to release the at least one output clock signal towards the next one of the semiconductor devices via at least one output clock signal line, the at least one output dock signal having a second dynamic range different than the first dynamic range.
